(19) United States
(12) Patent Application Publication
(10) Pub. No.: US 2004/0191639 A1
(43) Pub. Date: Sep. 30, 2004

(54) Micro-imprinting method and template for use in same

(76) Inventors: Danliang Jin, Bothell, WA (US); Jeffrey K. Kressbach, Snohomish, WA (US)

Correspondence Address: FISH & RICHARDSON P.C., 3300 DAIN RAUSCHER PLAZA, 60 SOUTH SIXTH STREET, MINNEAPOLIS, MN, 55402, US

(21) Appl. No.: 10/397,459

(22) Filed: Mar. 26, 2003

(51) Int. Cl. G03F 9/00; G03F 7/26

(52) U.S. Cl. 430/5; 430/311; 430/315

(57) ABSTRACT

A micro-imprinting method, and template for use in such a method, in which at least one surface of the template includes an alkyl silane release coating, where the alkyl silane is free of fluorine atoms.

### BACKGROUND OF THE INVENTION

All patents, patent applications, and publications cited within this application are incorporated herein by reference to the same extent as if each individual patent, patent application or publication was specifically and individually incorporated by reference.

The invention relates generally to micro-imprinting methods in which a relatively hard template (also referred to as a mask) contacts an imprintable composition. The imprintable composition can be a photoresist. The invention also relates to lithographic methods for creating microstructures in electrical insulating compositions, semi-conducting compositions, conducting compositions, or electro-optic compositions.

In a typical micro-imprinting process, a patterned template is placed in contact with an imprintable composition, thereby transferring, or imprinting, the template pattern on the composition. In some cases, the imprintable composition may be cured by exposure to radiation such that it can retain the imprinted shape after the template is removed, for example see Bailey et al., “Step and flash imprint lithography: Template surface treatment and defect analysis,” J. Vac. Sci. Tech. B 2000, 18(6), 3572-3577. In many cases, the imprintable composition sticks to the patterned mask so that removal of the patterned mask results in tearing of the imprinted microstructures. Such tearing can be large enough to cause defects in the microstructures. Defects can also result when particles stick to the patterned template.

Micro-imprinting methods can be part of lithographic processes, for example see Resnick et al. “Release Layers for Contact and Imprint Lithography,” Semicon. Int. 2002, June, 71-80. In a typical lithographic process, referring to FIG. 1a, a layered structure (1) comprising a substrate (2) that is to be micro-patterned and a radiation definable composition (3) is placed near a patterned lithographic mask (4) comprising radiation opaque regions (5) and a radiation transparent substrate (6). The radiation opaque regions (5) can be raised from the surface (7) of the radiation transparent substrate (6). Referring to FIG. 1b, when the radiation definable composition (4) is exposed to radiation (8) through the lithographic mask (4), the chemical structure of the radiation definable composition changes in the exposed areas (10). When the radiation curable composition is “positive tone” (such as in FIG. 1b), the radiation definable material is then developed to remove the areas of changed chemical structure (10) to leave the lithographic mask pattern (12) in the material. In a “negative tone” lithographic process, the areas of changed chemical structure in the radiation definable compositions are not removed during developing.

Lithographic mask patterns can be transferred to radiation curable compositions through “proximity printing” or “contact printing.” Referring to FIG. 1c, “proximity printing” involves placing the lithographic mask (4) close to the radiation definable composition (3) such that a small gap (14) exists. Referring to FIG. 1d, “contact printing” involves placing the lithographic mask (4) in contact with the radiation definable composition (3) such that the lithographic mask pattern is imprinted in the radiation definable composition (3) when the opaque regions (5) of the lithographic mask are raised from the surface (7) of the radiation transparent substrate (6). Contact printing is relatively simple, and can provide high wafer throughput and good resolution. However, when contact printing is used, problems with the radiation definable composition and particles sticking to the mask can result in defects in the substrate that is eventually patterned.

To alleviate problems associated with patterned templates, including lithographic masks, coatings have been applied to the surface of the templates in order to lower the surface energy and hinder adhesion. However, the approaches to date have been met with challenges including the durability of the coating, the expense of the chemicals, and undesirably high temperatures for processing the coated template.

### SUMMARY OF THE INVENTION

A method is described that comprises: a) providing a micro-patterned template having a first surface and a second surface where at least one of the surfaces further includes an alkyl silane, the alkyl silane containing no fluorine atoms; b) contacting the surface comprising the alkyl silane with an imprintable composition.

The micro-patterned template can be composed of materials such as metals, alloys, metal oxides, glass, quartz, and others, as well as combinations thereof. The imprintable composition can be chosen from materials such as polymers, oligomers, and others, as well as combinations thereof that have sufficient softness, i.e., sufficient softness relative to the micro-patterned template, to be imprinted. Preferably, the alkyl silane comprises at least one alkyl group that contains between about 12 and about 24 carbons, inclusive, and is a straight chain alkyl group.

The inventors have found that the alkyl silane release coating, by virtue of its relatively low surface energy, prevents the coated micro-patterned template from sticking to both particles and the imprintable composition during contact. Also, the coating can be applied at room temperature when there is an adequate amount of hydroxyl groups on surface of the micro-patterned template, which is accomplished after a standard cleaning procedure. The chemicals used for the coating are much cheaper than fluorinated coatings and can be cleaned with solvents and other commercial cleaners without affecting the release properties. The inventors have also found that the coating can be removed with basic water solutions.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 illustrates features of typical lithographic processes.

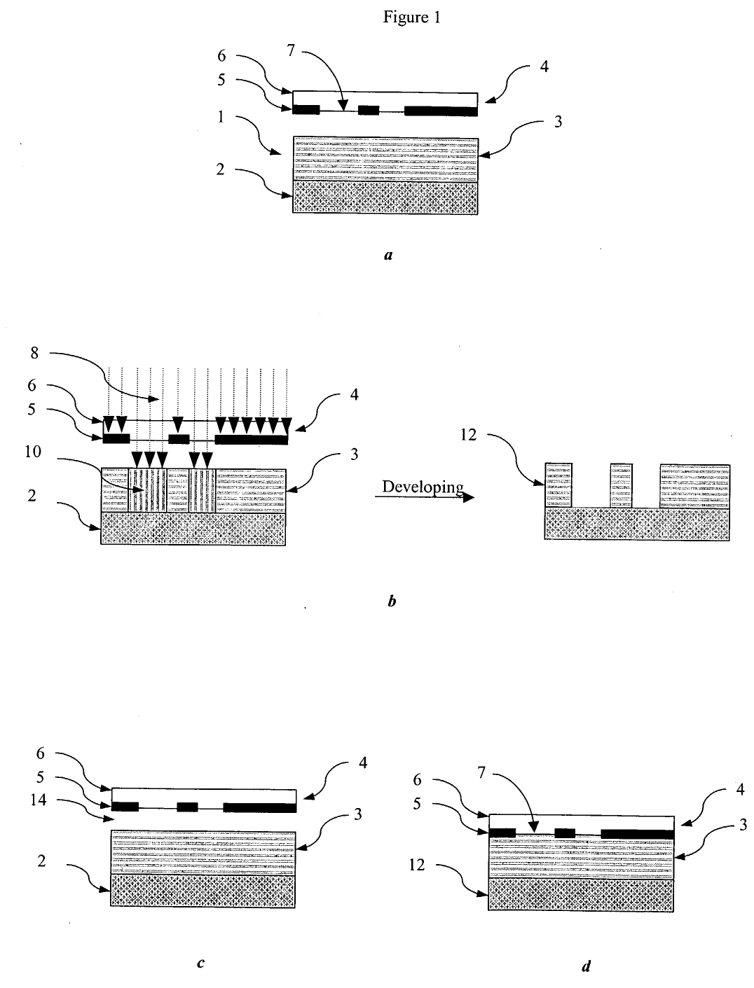

### DETAILED DESCRIPTION

In one embodiment, a method comprises: a) providing a micro-patterned template having a first surface and a second surface, where at least one surface of the template further includes an alkyl silane, where the alkyl silane contains no fluorine atoms and b) contacting the surface comprising the alkyl silane with an imprintable composition. The alkyl silane functions as a release coating that prevents particles or the imprintable composition from sticking to the mask. Preferably, the imprintable composition is a radiation definable composition. Radiation definable compositions are sometimes referred to as a “resists.” The resist may be a positive tone or a negative tone resist. Such resists may be cured by exposure to infra-red, visible, ultraviolet, or x-ray radiation. In another embodiment, the radiation definable composition is exposed to radiation. Preferably, the template is a photomask, the imprintable composition is a photoresist, and the radiation is ultraviolet light. Preferably, the alkyl silane comprises at least one alkyl group having between about 12 and about 24 carbons. Even more preferably, the alkyl group is a straight chain alkyl group.

The alkyl silane release coating may be formed by depositing an alkyl halosilane containing no fluorine atoms on the alkyl group on the micro-patterned surface of the mask and then curing the halosilane to form an alkyl silane coating covalently bonded to the mask surface. The alkyl halosilane may be deposited using methods such as spin coating, dip coating, brushing, and the like. Examples of useful alkyl halosilanes include chlorosilanes having 1-3 chlorine atoms and at least one alkyl group having between 12 and 24 carbon atoms, inclusive. Preferably, the alkyl group is a straight chain alkyl group. Since the method provides a route to articles with a reduced number of defects, it may be used to prepare microstructured articles such as passivation barriers, electrical interconnects, electrical transistors, optical interconnects, optical waveguides, electro-optic waveguides, and the like. Suitable materials for the microstructures include electrically insulating compositions, semi-conducting compositions, electrically conductive compositions, and electro-optic compositions. The microstructures may be formed directly in the imprintable composition. Alternatively, the microstructures may be defined in subsequent steps by, for example, dry etching or wet etching when the imprintable composition acts as an etch stop.

In another embodiment, a template comprises a) a first surface; b) a second surface; and c) a micro-pattern, where at least one surface further comprises an alkyl silane, the alkyl silane containing no fluorine atoms. Preferably, the alkyl silane comprises at least one alkyl group having between about 12 and about 24 carbons, inclusive. Even more preferably, the alkyl group is a straight chain alkyl group. In another embodiment, the template is a photomask.

### EXAMPLES

The following example(s) is illustrative and does not limit the claims.

In this example, the micro-patterned article is a photolithography mask, the imprintable composition is a radiation curable composition that is a positive tone photoresist, and the radiation curable composition is exposed to light.

The photolithography mask was composed of glass and the radiation opaque areas were a metal oxide. The mask was first cleaned with a commercial mask cleaner, then spin/rinse dried with 18 Meg/ohm water. A solution of 0.2% (by weight) of hexadecyltrichlorosilane in anhydrous toluene was spin deposited on the metal side of the photolithography mask at 500 rpm, followed by immediate ramping to 1000 rpm, where the mask was allowed to spin for 120 seconds. The substrate was then spun at 1000 rpm for 5 seconds, toluene was poured over the mask at 1000 rpm, and spinning continued at 1000 rpm for 30 seconds to dry the mask. The surface of the coated mask was very hydrophobic, resulting in high contact angles with water. The mask could be cleaned with solvents and commercial cleaners such as Nanostrip™ from Cyantek. The alkyl silane coating could be removed from the mask by treatment with 30% NaOH (aq) until the surface became hydrophilic.

The coated photolithography mask was placed in mask aligner and the coated side of the mask was brought into vacuum contact with a positive tone photoresist, SPR 220-1.2 from Shipley, on a 6 in. silicon wafer. The photoresist was then exposed to 365 nm ultraviolet light.

Other embodiments are within the following claims.

1. A method, comprising: a) providing a micro-patterned template having a first surface and a second surface, wherein at least one surface further comprises an alkyl silane, the alkyl silane containing no fluorine atoms and b) contacting the surface comprising the alkyl silane with an imprintable composition.

2. The method of claim 1, wherein the imprintable composition comprises a radiation-definable composition.

3. The method of claim 2, further comprising exposing the radiation-definable composition to radiation.

4. The method of claim 3, wherein the micro-patterned template is a photomask, the radiation-definable composition is a photoresist, and the radiation is ultraviolet light.

5. The method of claim 4, wherein the photoresist is a positive-tone photoresist.

6. The method of claim 4, wherein the photoresist is a negative-tone photoresist.

7. The method of claim 1, wherein the alkyl silane comprises at least one alkyl group having between about 12 and about 24 carbons, inclusive.

8. The method of claim 7, wherein the alkyl group is a straight chain alkyl group.

9. The method of claim 1, wherein the micro-pattern defines a plurality of microstructures selected from the group consisting of passivation barriers, electrical interconnects, electrical transistors, optical interconnects, optical waveguides, electro-optic waveguides, and combinations thereof.

10. A template, comprising a) a first surface; b) a second surface; and c) a micro-pattern, wherein at least one surface further comprises an alkyl silane, the alkyl silane containing no fluorine atoms.

11. The template of claim 10, wherein the template is a photomask.

12. The template of claim 10, wherein the alkyl silane comprises at least one alkyl group having between 12 and 24 carbons, inclusive.

13. The template of claim 12, wherein the alkyl group is a straight chain alkyl group.
